(19) United States
(12) Patent Application Publication
(10) Pub. No.: US 2021/0226467 A1
(43) Pub. Date: Jul. 22, 2021

(54) HIGH-DENSITY HEAT SINK FOR DISSIPATING HEAT FROM HEAT-GENERATING COMPONENTS

(71) Applicant: SCHNEIDER ELECTRIC IT CORPORATION, West Kingston, RI (US)

(72) Inventors: Lee Chien-An, New Taipei City (TW); Tasi Ping-Chung, New Taipei City (TW); Lee Kuo Liang, Taipei City (TW); Pang Jen-Shih, New Taipei City (TW); Chen Chung-Hui, New Taipei City (TW)

(21) Appl. No.: 16/749,385

(22) Filed: Jan. 22, 2020

(51) Int. Cl. H02J 7/00; H05K 7/20

(52) U.S. Cl. CPC H02J 7/00309; H05K 7/20163; H05K 7/20409; H05K 7/20209; H05K 7/20172

(57) ABSTRACT

A system is provided to dissipate heat from integrated circuit (IC) packages associated with a main printed circuit board of an uninterruptible power supply. The system includes a high-density heat sink fabricated from a thermally conductive material. The heat sink includes one interconnected wall configured to dissipate heat from components on a first printed circuit board including a first circuit and a second circuit, another interconnected wall configured to dissipate heat from components on a second printed circuit board, and another interconnected wall configured to dissipate heat from components on a third printed circuit board. In a first mode of operation, heat is generated by components in the first and second circuit, and in a second mode of operation, heat is generated by components on at least one of the second or the third printed circuit board and components in the second circuit.

### BACKGROUND OF THE INVENTION

### 1. Field of Invention

Aspects and embodiments disclosed herein relate generally to a system for dissipating heat from heat-generating components, and more specifically to a system for dissipating heat from electronic components that are mountable on a printed circuit board (PCB).

### 2. Discussion of Related Art

Modern electronic components produce excessive amounts of heat during operation. To ensure that the components do not overheat, system designers attach convective heat sinks to cool these components, by providing an efficient heat transfer path from the devices to the environment. A convective heat sink is designed to transfer heat energy from the high temperature component to lower temperature of the surrounding air. Such heat sinks attach to the components through a base and include fins or pins to increase the surface area of the heat sink within a given space. Heat can be generated from various electronic components mounted on a PCB.

Existing PCBs can be configured to have multiple heat sinks designed to dissipate heat from various heat-generating electronic components mounted thereon. FIGS. 1A and 1B provide examples of PCBs 10, 14, respectively, with multiple heat sinks mounted thereon. As shown in FIG. 1A, heat sinks 12a, 12b, 12c are mounted on PCB 10 to dissipate heat from the respective electronic components to which they are attached. Similarly, as shown in FIG. 1B, several electronic components are mounted on PCB 14, such as electronic component 16. As shown, heat sinks 18a, 18b are secured to the PCB 14 to remove heat from the components 16.

The structures disclosed in FIGS. 1A and 1B show that as the number of heat sinks on a PCB increases, so does the surface area of the PCB to accommodate the heat sinks. In certain applications where PCBs are used, such as in an uninterruptible power supply (UPS) device, space is at a premium, which creates a need to reduce the sizes of PCBs used in the UPS. Additionally, the larger in size a PCB, the more expensive it becomes to manufacture and transport.

### SUMMARY OF THE INVENTION

One aspect of the present disclosure is directed to a system for dissipating heat from a plurality of integrated circuit (IC) packages associated with a main printed circuit board of an uninterruptible power supply, with the system being configured to operate in one of at least two modes of operation. In one embodiment, the system comprises a high-density heat sink fabricated from a thermally conductive material. The high-density heat sink includes a body having interconnected walls, a first open end, and a second open end in fluid communication with the first open end. The interconnected walls define a cavity, with each interconnected wall of the interconnected walls having an outer surface and an inner surface. A first interconnected wall is configured to dissipate heat from components on a first printed circuit board comprising a first circuit and a second circuit. An outer surface of at least one second interconnected wall of the interconnected walls is configured to dissipate heat from components on a second printed circuit board. An outer surface of at least one third interconnected wall of the interconnected walls is configured to dissipate heat from components on a third printed circuit board. The high-density heat sink further includes a plurality of fins formed on an inner surface of at least one interconnected wall of the interconnected walls. In a first mode of operation, heat is generated by components in the first and second circuit, and in a second mode of operation, heat is generated by components on at least one of the second or the third printed circuit board and components in the second circuit.

Embodiments of the system further may include a fan positioned proximate to the first open end or the second open end of the body, the fan being configured to provide directed airflow through the cavity of the high-density heat sink over the plurality of fins. The interconnected walls may be configured to conduct heat from the plurality of IC packages to the plurality of fins. At least one of the plurality of IC package may contain an IC configured to provide at least one of AC to DC power conversion, power factor correction, DC to DC power conversion, or DC to AC power conversion. At least one IC package of the plurality of IC packages may have an upper side and a lower side, with the upper side of the at least one IC package being secured by thermal adhesive to an outer surface of an interconnected wall of the interconnected walls of the high-density heat sink. The system further may include a layer of thermal paste between the at least one IC package and the outer surface of the interconnected wall of the interconnected walls of the high-density heat sink, the layer of thermal paste being configured to provide thermal coupling between the at least one IC package and the outer surface of the interconnected wall of the high-density heat sink. The high-density heat sink further may include supports formed integrally with the first interconnected wall of the high-density heat sink. The supports may be configured to elevate the body of the high-density heat sink such that at least one IC package can be secured to an outer surface of the first interconnected wall of the high-density heat sink. The plurality of IC packages may be mounted on a second printed circuit board. The high-density heat sink may be part of an uninterruptible power supply (UPS). The second printed circuit board may have a first side and a second side, with the first side of the second printed circuit board being in contact with the outer surface of the at least one second interconnected wall. At least one IC package may be mounted on the second side of the second printed circuit board. The second printed circuit board may be configured to have at least one vertical interconnect access (via), with the at least one via allowing heat to be transferred from the at least one IC package on the second side of the second printed circuit board to the outer surface of the at least one second interconnected wall of the high-density heat sink. The at least one second interconnected wall of the high-density heat sink may be configured to transfer heat from the at least one IC package to the plurality of fins. The system further may include a layer of thermal paste between an first side of the second printed circuit board and the outer surface of the at least one second interconnected wall of the high-density heat sink. The layer of thermal paste may be configured to provide thermal coupling between the first PCB and the at least one second interconnected wall of the high-density heat sink. The high-density heat sink may include supports formed integrally with the first interconnected wall of the high-density heat sink, with the supports being configured to elevate the body of the high-density heat sink such that at least one IC package can be secured to an outer surface of the first interconnected wall of the high-density heat sink. At least two fins of the plurality of fins have different lengths.

Another aspect of the disclosure is directed to a system for controlling dissipation of heat from a plurality of integrated circuit (IC) packages associated with an uninterruptible power supply. In one embodiment, the system comprises a high-density heat sink, which is fabricated from a thermally conductive material. The high-density heat sink includes a body having interconnected walls, and a plurality of fins formed on an inner surface of at least one interconnected wall of the interconnected walls. The system further includes a fan positioned proximate to an end of the body, with the fan being configured to provide directed airflow through the high-density heat sink over the plurality of fins. The system further includes a controller coupled to the fan to control the operation of the fan. The controller is configured to operate the fan from a low speed mode to a high speed mode when one of the following conditions are met: a) an internal ambient temperature of the uninterrupted power supply is greater than a first predetermined temperature, b) a maximum load of the uninterruptible power supply is greater than a first predetermined load percent, or c) an input current of the uninterruptible power supply is greater than a first predetermined current.

Embodiments of the system further may include configuring the controller to operate the fan from the high speed mode to the low speed mode when at least one of the following conditions is met d) the internal ambient temperature of the uninterrupted power supply is less than a second predetermined temperature, e) the maximum load of the uninterruptible power supply is less than a second predetermined load percent, and f) the input current of the uninterruptible power supply is less than a second predetermined current. The first predetermined temperature may be approximately 45° C. and the second predetermined temperature may be approximately 40° C. The first low speed mode may be approximately 70% of fan speed.

Yet another aspect of the disclosure is directed to a method of assembling a heat sink to a main printed circuit board of an uninterruptible power supply. The heat sink is configured to dissipate heat from a plurality of integrated circuit (IC) packages associated with the main printed circuit board of the uninterruptible power supply. In one embodiment, the method comprises: securing a high-density heat sink to the main printed circuit board of the uninterruptible power supply, the high-density heat sink being fabricated from a thermally conducting material and including a body having interconnected walls, a first open end, and a second open end in fluid communication with the first open end, the interconnected walls defining a cavity, each interconnected wall of the interconnected walls having an outer surface and an inner surface, a first interconnected wall being of the interconnected walls secured to the main printed circuit board, and an outer surface of at least one second interconnected wall of the interconnected walls being configured to support the at least one IC package of the plurality of IC packages, and a plurality of fins formed on an inner surface of at least one interconnected wall of the interconnected walls; mounting at least one IC package of the plurality of IC packages on a first side of a second printed circuit board; and securing a first side of the second printed circuit board to an outer surface of a second interconnected wall of the interconnected walls of a high-density heat sink. In a first mode of operation, the method further includes dissipating heat generated from the main printed circuit board by the first interconnected wall of the high-density heat sink. In a second mode of operation, the method further includes dissipating heat generated from the at least one IC package by the second interconnected wall of the high-density heat sink.

Embodiments of the method further may include providing directed airflow through the cavity of the high-density heat sink over the plurality of fins. The first PCB may have at least one vertical interconnect access (via), with the at least one via allowing for heat transfer between the at least one IC package and the outer surface of the interconnected wall of the high-density heat sink. The method further may include applying a thermal paste on the outer surface of the interconnected wall of the high-density heat sink, with the thermal paste being configured to provide thermal coupling between the outer surface of the interconnected wall of the high-density heat sink and the lower side of the first PCB. At least two fins of the plurality of fins have different lengths.

Another aspect of the disclosure is directed to a method of controlling dissipating heat from a plurality of integrated circuit (IC) packages associated with an uninterruptible power supply. In one embodiment, the method comprises: mounting at least one IC package of the plurality of IC packages on a high-density heat sink, with the high-density heat sink being fabricated from a thermally conducting material and including a body having interconnected walls, a first open end, and a second open end in fluid communication with the first open end, the interconnected walls defining a cavity, each interconnected wall of the interconnected walls having an outer surface and an inner surface, an outer surface of an interconnected wall of the interconnected walls being configured to support the at least one IC package, and a plurality of fins formed on an inner surface of at least one wall of the interconnected walls; moving air through the cavity of the high-density heat sink with a fan positioned proximate to the first open end or the second open end of the body, the fan being configured to provide directed airflow through the cavity of the high-density heat sink over the plurality of fins; and controlling the operation of the fan with a controller coupled to the fan, the controller being configured to operate the fan from a first low speed mode to a second high speed mode when one of the following conditions are met a) an internal ambient temperature of the uninterrupted power supply is greater than a first predetermined temperature, b) a maximum load of the uninterruptible power supply is greater than a speed power limit of the fan, and c) an input current of the uninterruptible power supply is greater than a predetermined current.

Embodiments of the method further may include configuring the controller to operate the fan from the second high speed mode to the first low speed mode when one of the following conditions is met d) an internal ambient temperature of the uninterrupted power supply is less than a second predetermined temperature, e) a maximum load of the uninterruptible power supply is less than a speed power limit of the fan, and f) an input current of the uninterruptible power supply is less than the predetermined current. The first predetermined temperature may be approximately 45° C. and the second predetermined temperature may be approximately 40° C. The first low speed mode may be approximately 70% of fan speed.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the aspects and embodiments disclosed herein.

In the figures, each identical or nearly identical component that is illustrated in various figures is represented by a like numeral. For purposes of clarity, not every component may be labeled in every figure. In the figures:

FIG. 1A is a view illustrating a PCB with multiple heat sinks;

FIG. 1B is a view illustrating another PCB with multiple heat sinks;

FIG. 2 is an exploded perspective view illustrating a first embodiment of a heat dissipation system in a disassembled condition in accordance with aspects disclosed herein;

FIG. 3A is a perspective view illustrating the heat dissipation system of FIG. 2 in an assembled condition in accordance with aspects disclosed herein;

FIG. 3B is a perspective view taken from another perspective of the heat dissipation system of FIG. 2 in an assembled condition in accordance with aspects disclosed herein;

FIG. 3C is an end view of the heat dissipation system of FIG. 2 in an assembled condition in accordance with aspects disclosed herein;

FIG. 4 is a front view of an example in which the heat dissipation system of FIGS. 2-3C is mounted on a PCB of a UPS device in accordance with aspects disclosed herein;

FIG. 5A is a front view of an example of a conduction path, on the PCB of FIG. 4, in an online mode of the UPS device in accordance with aspects disclosed herein;

FIG. 5B is a front view of an example of a conduction path, on the PCB of FIG. 4, in a battery mode of the UPS device in accordance with aspects disclosed herein;

FIG. 6A is a front view of the heat-generating components in the online mode of the UPS device, and heat dissipation therefrom using the heat dissipation system of FIGS. 2-3C, in accordance with aspects disclosed herein;

FIG. 6B is a front view of the heat-generating components in the battery mode of the UPS device, and heat dissipation therefrom using the heat dissipation system of FIGS. 2-3C, in accordance with aspects disclosed herein;

FIG. 7 is a perspective view of components of the UPS illustrating airflow through and around the heat-dissipation system of FIGS. 2-3C in accordance with aspects disclosed herein;

FIG. 8 is an end view of a heat dissipation system of another embodiment of the present disclosure;

FIG. 9 is an end view of a heat dissipation system of another embodiment of the present disclosure;

FIG. 10 is an end view of a heat dissipation system of another embodiment of the present disclosure; and

FIG. 11 is an end view of a heat dissipation system of another embodiment of the present disclosure.

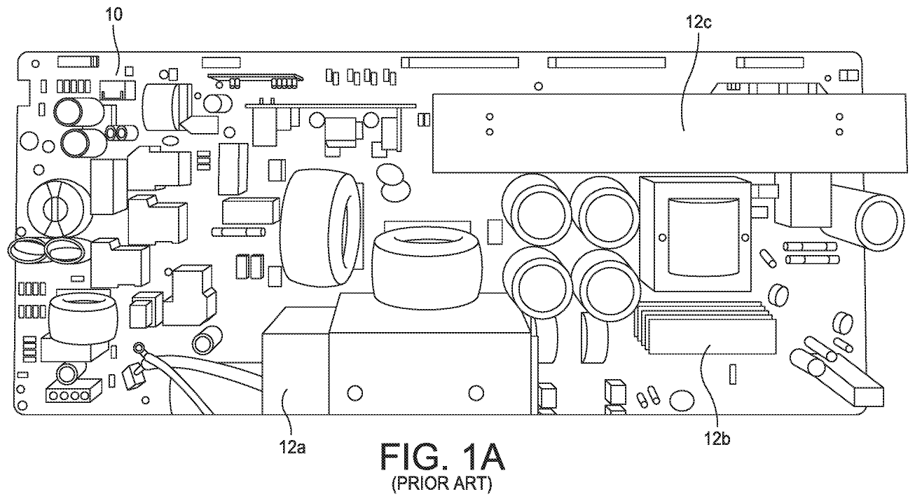

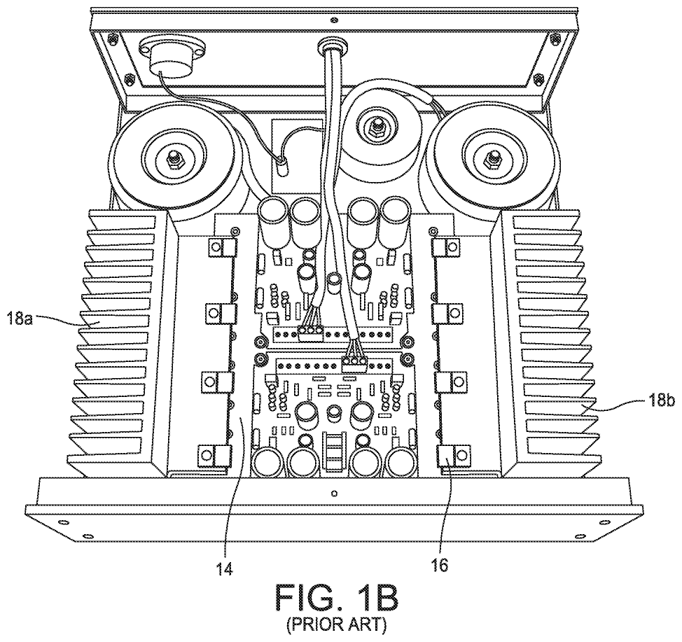

### DETAILED DESCRIPTION

At least some embodiments disclosed herein provide a heat dissipation system for dissipating heat from heat-generating components. In particular, at least some embodiments are directed to a heat dissipation system for dissipating heat from electronic components mountable on a PCB. The heat dissipation system disclosed herein is designed to eliminate the need for having multiple heat sinks on a PCB. The heat dissipation system disclosed herein allows for a PCB assembly with a smaller surface area and a smaller heat sink volume to be designed and used in applications where space is at a premium, such as in UPS devices.

Various aspects of the heat-dissipation system will now be discussed in detail with reference to the accompanying drawings. It is to be appreciated that this system is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having”, “containing,” “involving,” and variations thereof herein, is meant to encompass the items listed thereafter and equivalents thereof as well as additional items.

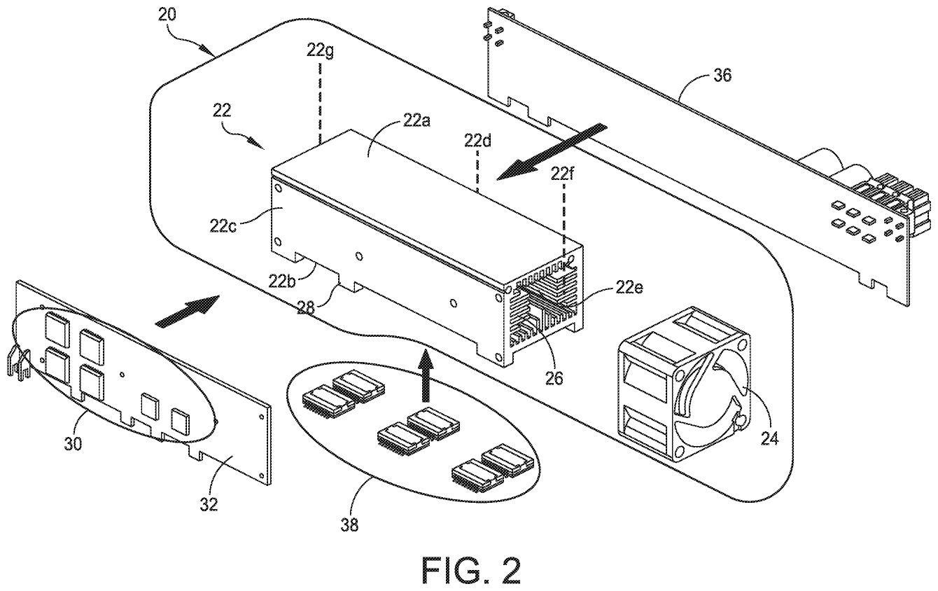

Referring to FIG. 2, a heat dissipation system, generally indicated at 20, includes a high-density heat sink 22 and a fan 24 to move air across the high-density heat sink 22. In one embodiment, the high-density heat sink 22 is fabricated from a thermally conductive material, such as aluminum. It should be understood that a person skilled in the art given the benefit of the present disclosure can fabricate the high-density heat sink 22 out of any suitable material that is traditionally used in heat sink applications. In the embodiment shown in FIG. 2, the high-density heat sink 22 has four walls 22a, 22b, 22c, 22d and two open ends 22f and 22g. The walls 22a, 22b, 22c, 22d of the high-density heat sink 22 define a cavity 22e, with each wall having an outer surface and an inner surface. Additionally, the high-density heat sink 22 includes supports 28 that are formed integrally with wall 22b such that the outer surface of wall 22b is elevated with respect to a structure on which the high-density heat sink 22 is mounted.

With continued reference to FIG. 2, a plurality of fins 26 are formed on the inner surfaces of the walls 22a, 22b, 22c, 22d of the high-density heat sink 22. In one embodiment, the fins can vary in length with respect to one another, with at least two of the plurality of fins 26 being of different lengths. Forming the plurality of fins 26 as shown in FIG. 2 makes use of the cavity 22e and increases the surface area over which heat can be conducted, thereby increasing the rate of heat transfer. The arrangement is such that as the fan 24 delivers air through the cavity 22e of the high-density heat sink 22 to promote heat dissipation. The fan 24 may be selected to be of a suitable type and size that is compatible with the high-density heat sink 22, as would be understood by those skilled in the art, given the benefit of this disclosure.

It is to be appreciated that heat-generating electronic components, such as integrated circuit (IC) packages, can be connected to the high-density heat sink 22 in multiple ways. For example, IC packages can be directly connected to an outer surface of at least one wall of the high-density heat sink 22; mounted on a PCB, which is then secured to an outer surface of a wall of the high-density heat sink 22; and/or connected on one side to a heat spreader, which is then secured to an outer surface of a wall of the high-density heat sink 22. Alternatively, a combination of the aforementioned methods can be used to attach or connect heat-generating electronic components to walls 22a, 22b, 22c, 22d of the high-density heat sink 22. Walls 22a, 22b, 22c, 22d of the high-density heat sink 22 transfer heat from the IC packages or other heat-generating electronic components to the plurality of fins 26.

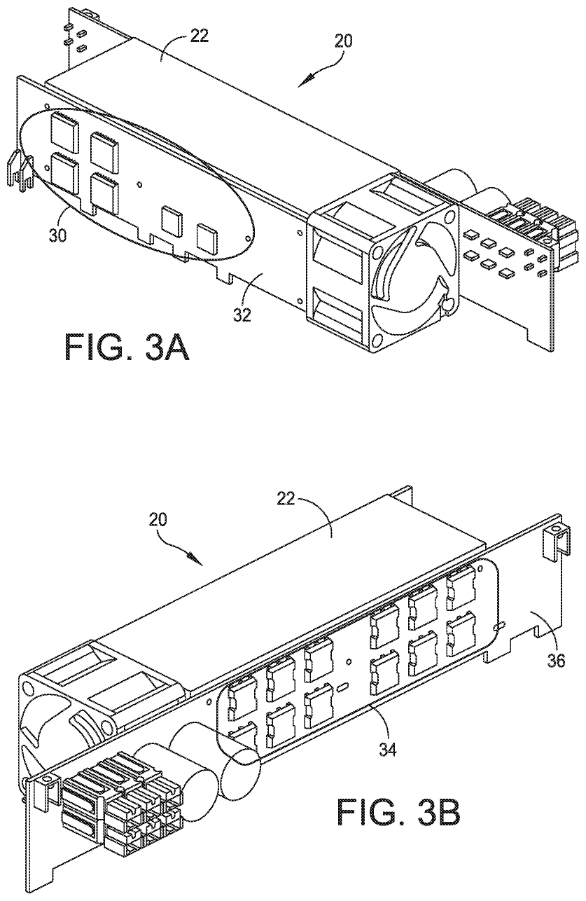

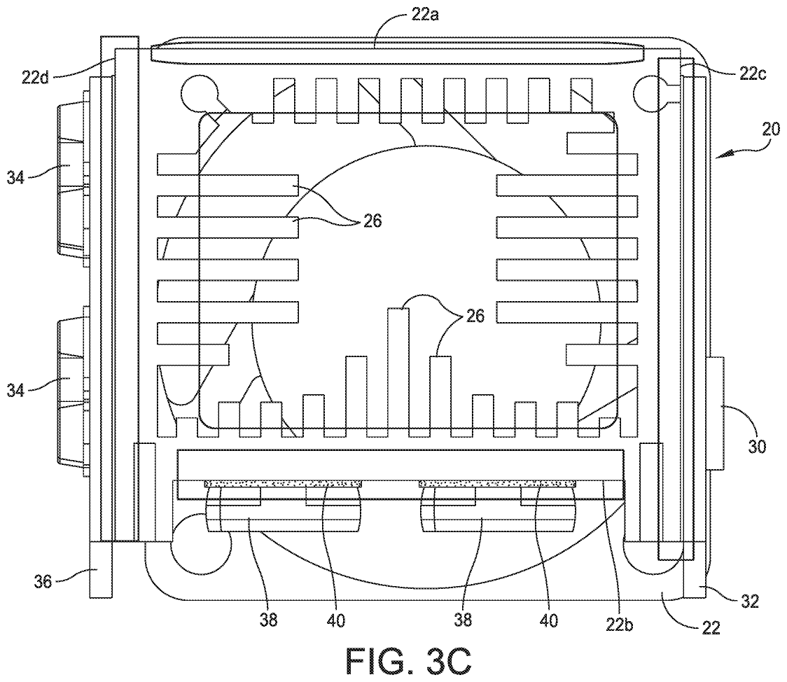

In the embodiment shown in FIG. 2, a first group of IC packages 30 are mounted on PCB 32, which can be secured to, for example, wall 22c of the high-density heat sink 22. A second group of IC packages 34 (shown in FIG. 3A) are mounted on PCB 36, which can be secured to, for example, wall 22d of the high-density heat sink 22. A third group of IC packages 38 have a first side connected to wall 22b and a second side secured to a PCB (not shown) on which the heat dissipation system 20 can be mounted. The outer surfaces of the walls 22a, 22b, 22c, 22d are provided to mount any number of electronic components in a variety of ways, and the configuration shown in FIGS. 3A-3C are exemplary.

Furthermore, PCBs 32 and 36 are designed to have a plurality of vertical interconnect accesses (vias). When PCBs 32, 36 are secured to walls 22c, 22d, respectively, the vias allow heat to be transferred from the IC packages mounted on PCBs 32, 36 to the outer surface of each of walls 22c, 22d, respectively. Other components can be employed to facilitate the heat transfer from the IC packages and the PCBs 32, 36 to the walls 22c, 22d of the high-density heat sink 22.

FIGS. 3A-3C illustrate the heat dissipation system 20 in an assembled form, with the heat-generating electronic components connected or attached to the high-density heat sink 22. As shown in FIG. 3A, the first group of IC packages 30 are mounted on PCB 32, which is secured to the high-density heat sink 22. Similarly, as shown in FIG. 3B, the second group of IC packages 34 are mounted on PCB 36, which is secured to the high-density heat sink 22. FIG. 3C is an end view of the high-density heat sink 22 illustrating how the different groups of IC packages are attached or connected to the different walls of the high-density heat sink 22.

In the embodiment shown in FIG. 3C, a first side of the third group of IC packages 38 is secured to a thermal adhesive 40, which is applied to the outer surface of wall 22b of the high-density heat sink 22. A second side of the third group of IC packages 38 is connected to a PCB (not shown) on which the heat sink 22 and the fan 24 of the heat dissipation system 20 may be mounted. In one embodiment, the thermal adhesive 40 can be a suitable thermally conductive glue that is used to mount electronic components onto heat sinks. For example, the thermal adhesive can be a paste, such as a thermal paste, or double-sided tape. The thermal adhesive enables an improved heat exchange between the third group of IC packages 38 and the outer surface of wall 22b.

It is to be appreciated that a layer of thermal adhesive or paste may be applied to the outer surface of any wall of the high-density heat sink 22. The layer of thermal paste allows for an enhanced thermal coupling between the outer surface of a wall and a surface of a PCB, IC package, or any other component secured thereto. For example, the thermal paste can be placed between IC packages 34 and wall 22d.

Furthermore, in the assembled form of the heat dissipation system 20 shown in FIGS. 3A-3C, the fan 24 is positioned proximate to one of the open ends 22f and 22g of the high-density heat sink 22. As mentioned above, the fan 24 is configured to provide directed airflow through the cavity 22e of the high-density heat sink, and over the plurality of fins 26, to accelerate the dissipation of heat from the high-density heat sink 22.

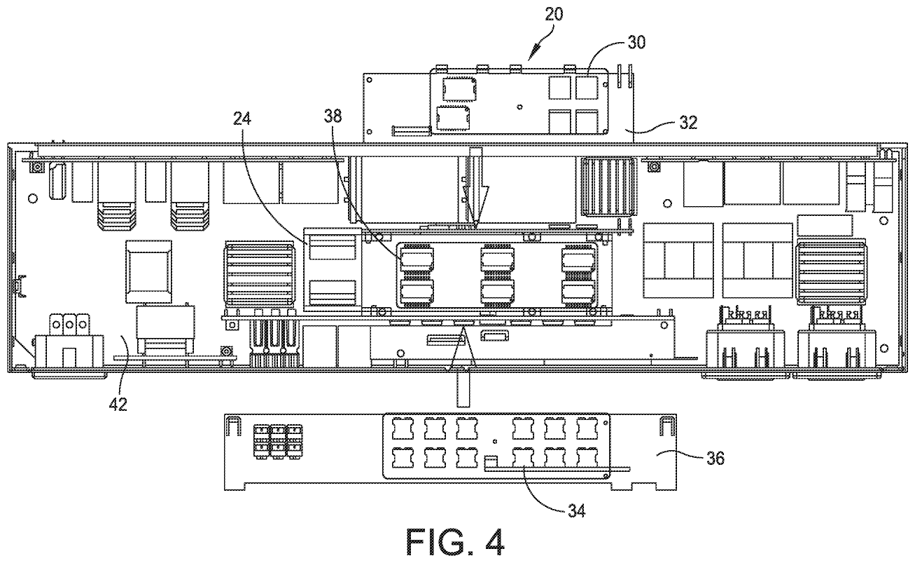

Referring to FIG. 4, an example of mounting the heat sink 22 and the fan 24 of the heat dissipation system 20 on PCB 42 is provided. In this example, PCB 42 is a main PCB of an online UPS device.

A conventional online UPS device rectifies input power provided by an electric utility using a Power Factor Correction (PFC) circuit to provide power to a DC bus. The rectified DC voltage is typically used to charge a battery while mains power is available, as well as to provide power to the DC bus. In the absence of mains power, the battery provides power to the DC bus. From the DC bus, a DC-AC inverter (INV) generates an AC output voltage to a load. In one embodiment, the PFC may be referred to as a first circuit and the INV may be referred to as a second circuit.

In some embodiments, the UPS device is configured to convert a low DC voltage, e.g., power from the battery, to a high DC voltage, with the high DC voltage being directed to the DC-AC inverter.

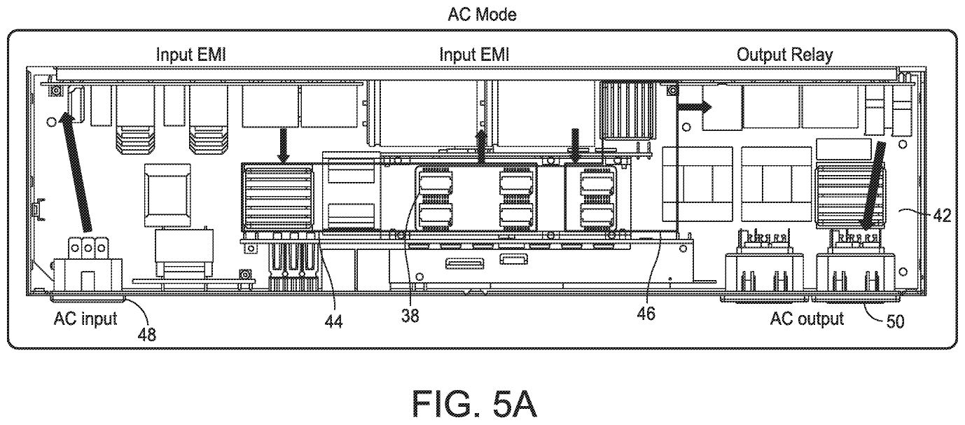

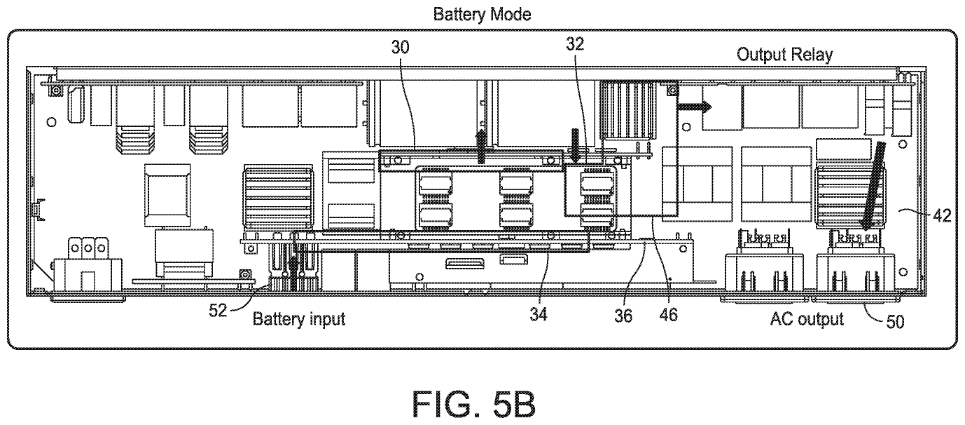

Referring to FIG. 5A, an example of a conduction path on PCB 42 of FIG. 4 is shown. In one configuration, the conduction path shown in an online mode of the online UPS device within which PCB 42 is housed. In the online mode, the power factor correction section 44 of PCB 42 rectifies AC power from AC input 48 to provide power to a DC bus (not shown). From the DC bus, a DC-AC inverter in the DC-AC inverter section 46 of the PCB 42 generates an AC output voltage to AC output 50. In this example, the electronic components used in the PFC section 44 and the DC-AC inverter section 46 are the third group of IC packages 38 (also shown in FIGS. 2, 3C and 4) that have a first side connected to the outer surface of wall 22b of the high-density heat sink 22 and a second side to a PCB, which in this case is PCB 42.

Referring to FIG. 5B, an example of a conduction path on PCB 42 of FIG. 4 is shown; the conduction path shown is with respect to a battery mode of the online UPS device within which PCB 42 is housed. In the battery mode, a battery provides DC power through battery input 52 to the DC bus (not shown). The DC power provided at battery input 52 is converted from one voltage level to another using DC-DC conversion devices such as the second group of IC packages 34 mounted on PCB 36 as well as the first group of IC packages 30 on PCB 32. Following the DC-DC power conversion, a DC-AC inverter in the inverter section 46 generates an AC output voltage to AC output 50. The electronic components used in the DC-AC inverter section 46 are a subgroup of the third group of IC packages 38 that have a first side connected to the outer surface of wall 22b of the high-density heat sink 22 and a second side to a PCB, which in this case is PCB 42.

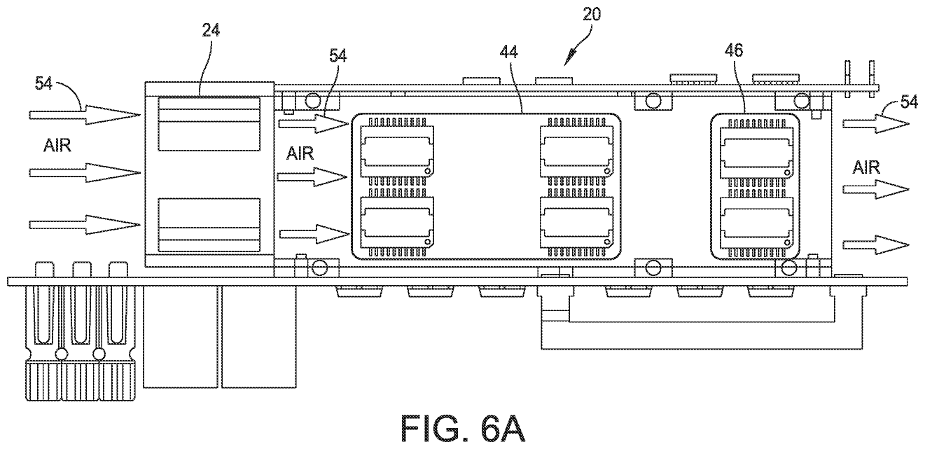

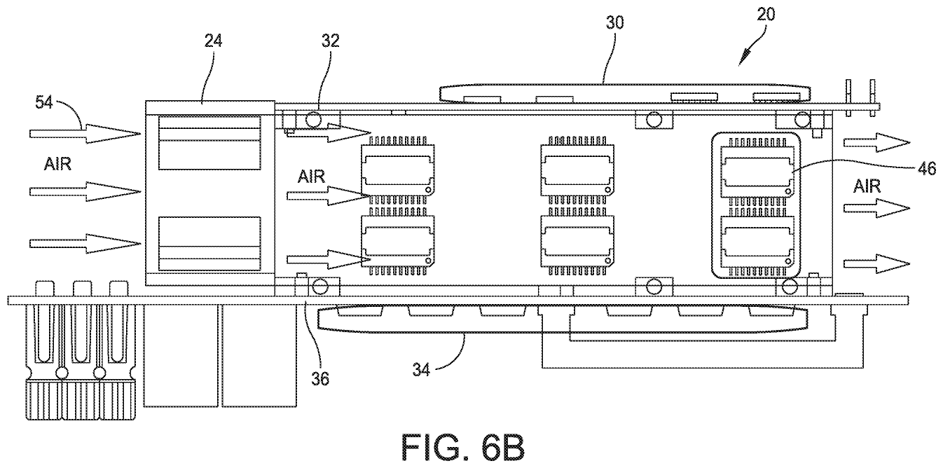

FIGS. 6A and 6B illustrate the sources of heat on PCB 42 in each mode of the UPS as discussed above with reference to FIGS. 5A and 5B.

Referring to FIG. 6A, heat is generated from PFC section 44 (the first circuit) and inverter section 46 (the second circuit). The third group of IC packages 38 provide PFC and DC-AC power conversion in the online mode, and, in so doing, they generate heat. As discussed above, the heat generated from the third group of IC packages 38 is conducted to the plurality of fins 26 (shown in FIGS. 2 and 3C) of the high-density heat sink 22. The heat is dissipated with the assistance of the fan 24, which provides directed airflow, represented by arrows 54, through the cavity 22e (shown in FIGS. 2 and 3C) and over the plurality of fins 26 of the high-density heat sink 22.

Referring to FIG. 6B, heat is generated from the first group of IC packages 30 mounted on PCB 32 as well as from IC packages 34 mounted on PCB 36. The first and second groups of IC packages provide DC-DC power conversion, and, in so doing, they generate heat. As discussed above, the heat generated from the plurality of IC packages 30 and the plurality of IC packages 32 is conducted to the plurality of fins 26 of the high-density heat sink 22. The heat is dissipated with the assistance of the fan 24, which provides directed airflow, represented by arrows 54, through the cavity 22e and over the plurality of fins 26 of the high-density heat sink 22.

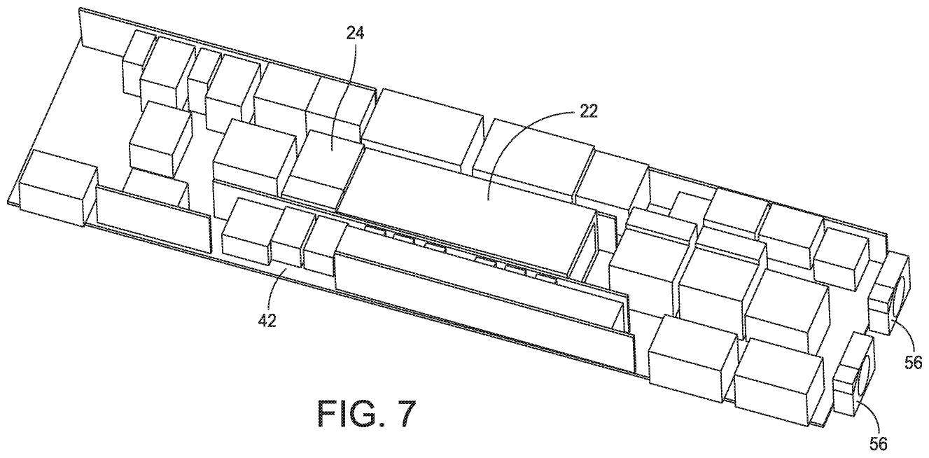

FIG. 7 illustrates the air streams created when the fan 24 is activated. PCB 42 may include additional fans, such as fans, each indicated at 56, positioned downstream of the fan 24, to further guide the air streams after passing through and around the high-density heat sink 22, cooling PCB 42 as a whole. The high-density heat sink 22 is configured to facilitate smooth airflow through components mounted on the PCB 42 thereby facilitating heat dissipation.

It should be understood that the high-density heat sink 22 and the fan can be configured to meet a particular need. The high-density heat sink 22 is configured to use three surfaces to mount and cool PCBs having heat-generating components. The high-density heat sink 22 of embodiments of the present disclosure results in a significant reduction in size and cost of the overall assembly. For example, embodiments of the high-density heat sink 22 can be configured to reduce PCB size (surface area) by 60%, while enabling high power (e.g., 3 kW) UPS designs.

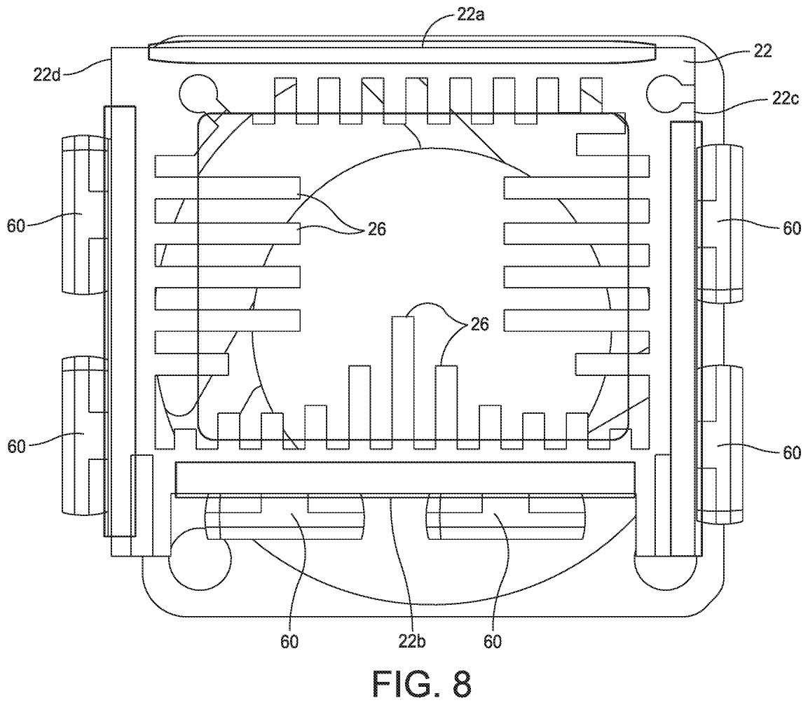

In one example, with reference to FIG. 8, the IC packages, each indicated at 60, are secured directly to the high-density heat sink 22. As shown, IC packages 60 are secured directly to walls 22b, 22c, 22d of the high-density heat sink 22. The IC packages 38 can be secured to the walls 22b, 22c, 22d of the high-density heat sink 22 by any suitable method, such as using thermal adhesive or paste. In one embodiment, the thermal adhesive or paste can be applied between a thermal spreader associated with the IC package 60.

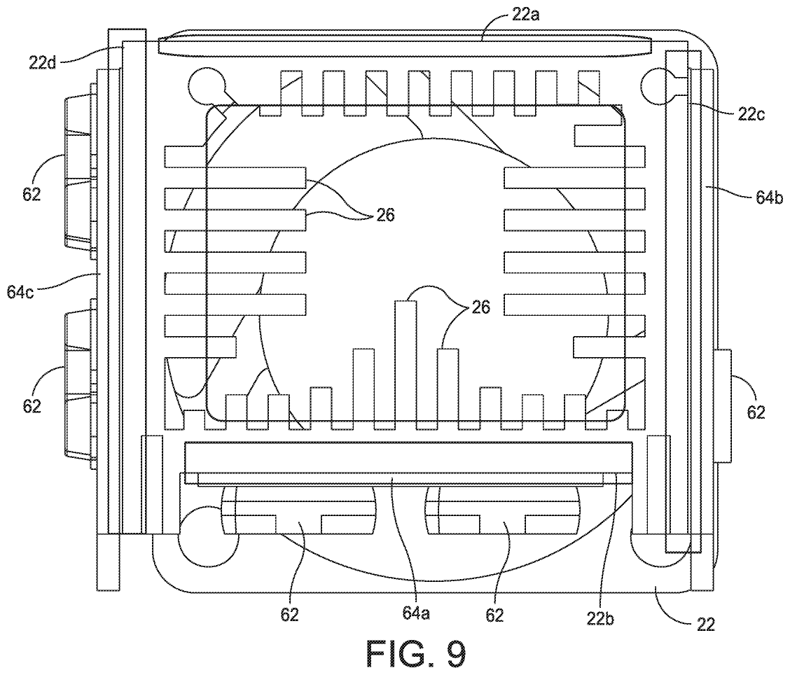

In another example, with reference to FIG. 9, the IC packages, each indicated at 62, are attached to PCBs 64a, 64b, 64c, which are secured to the high-density heat sink 22. In one embodiment, a thermal adhesive or paste can be used to secure the IC packages 62 to their respective PCBs 64a, 64b, 64c. As shown, the PCBs 64a, 64b, 64c are secured directly to the walls 22b, 22c, 22d of the high-density heat sink 22, respectively.

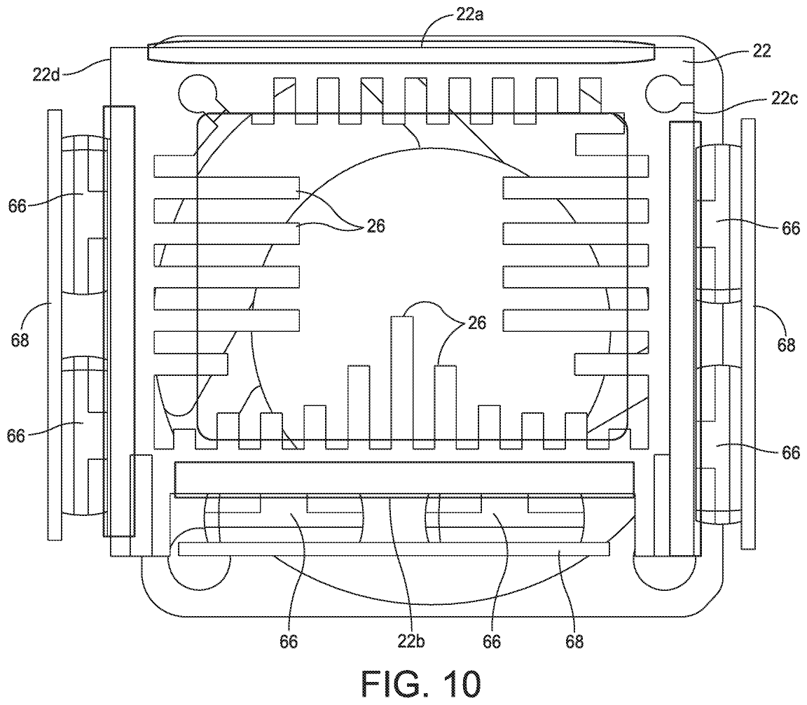

In another example, with reference to FIG. 10, the IC packages, each indicated at 66, are secured directly to the high-density heat sink 22. As shown, IC packages 66 are secured directly to walls 22b, 22c, 22d of the high-density heat sink 22 using, for example, thermal adhesive or paste. The IC packages 66 provided on each wall 22b, 22c, 22d are attached or secured to a PCB, indicated at 68. The IC packages 66 can be secured to the PCB 68 by any suitable method.

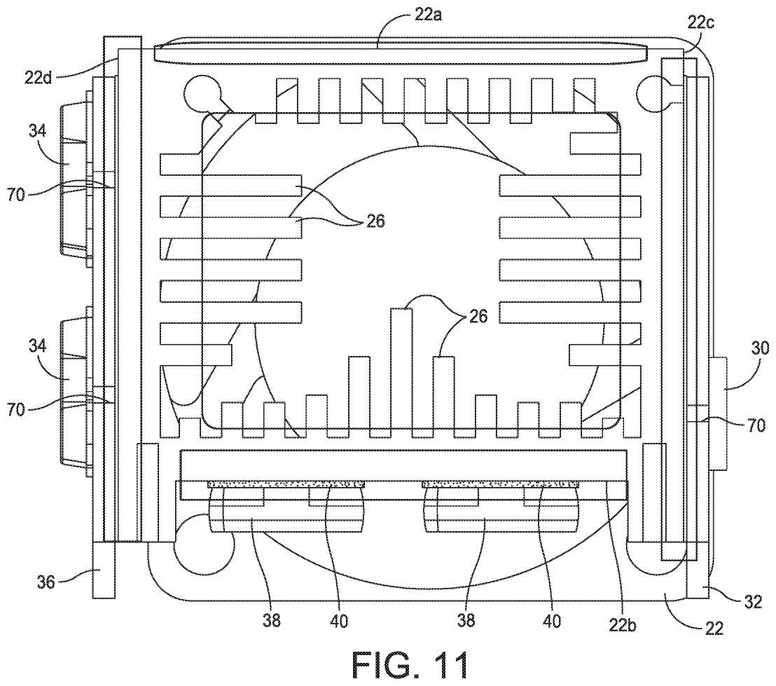

In another embodiment, with reference to FIG. 11, the configuration is similar to that shown in FIG. 3C. As shown, the first group of IC packages 30 are mounted on PCB 32, which is secured to the high-density heat sink 22. The second group of IC packages 34 are mounted on PCB 36, which is secured to the high-density heat sink 22. The first side of the third group of IC packages 38 is secured to outer surface of wall 22b of the high-density heat sink 22 by thermal adhesive or paste. As shown, vias, each indicated at 70, are formed in PCBs 32, 36 to transfer heat from the IC packages 30, 34 to the high-density heat exchanger 22.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A system for dissipating heat from a plurality of integrated circuit (IC) packages associated with a main printed circuit board of an uninterruptible power supply, the system being configured to operate in one of at least two modes of operation, the system comprising:
a high-density heat sink fabricated from a thermally conductive material, the high-density heat sink including
a body having interconnected walls, a first open end, and a second open end in fluid communication with the first open end, the interconnected walls defining a cavity, each interconnected wall of the interconnected walls having an outer surface and an inner surface, a first interconnected wall being configured to dissipate heat from components on a first printed circuit board comprising a first circuit and a second circuit, an outer surface of at least one second interconnected wall of the interconnected walls being configured to dissipate heat from components on a second printed circuit board, and an outer surface of at least one third interconnected wall of the interconnected walls being configured to dissipate heat from components on a third printed circuit board, and
a plurality of fins formed on an inner surface of at least one interconnected wall of the interconnected walls,
wherein in a first mode of operation, heat is generated by components in the first and second circuit, and in a second mode of operation, heat is generated by components on at least one of the second or the third printed circuit board and components in the second circuit.

2. The system of claim 1, further comprising a fan positioned proximate to the first open end or the second open end of the body, the fan being configured to provide directed airflow through the cavity of the high-density heat sink over the plurality of fins.

3. The system of claim 1, wherein the interconnected walls are configured to conduct heat from the plurality of IC packages to the plurality of fins.

4. The system of claim 1, wherein at least one of the plurality of IC package contains an IC configured to provide at least one of AC to DC power conversion, power factor correction, DC to DC power conversion, or DC to AC power conversion.

5. The system of claim 1, wherein at least one IC package of the plurality of IC packages has an upper side and a lower side, the upper side of the at least one IC package being secured by thermal adhesive to an outer surface of an interconnected wall of the interconnected walls of the high-density heat sink.

6. The system of claim 5, further comprising a layer of thermal paste between the at least one IC package and the outer surface of the interconnected wall of the interconnected walls of the high-density heat sink, the layer of thermal paste being configured to provide thermal coupling between the at least one IC package and the outer surface of the interconnected wall of the high-density heat sink.

7. The system of claim 1, wherein the high-density heat sink further includes supports formed integrally with the first interconnected wall of the high-density heat sink, the supports being configured to elevate the body of the high-density heat sink such that at least one IC package can be secured to an outer surface of the first interconnected wall of the high-density heat sink.

8. The system of claim 1, wherein the plurality of IC packages are mounted on a second printed circuit board.

9. The system of claim 1, wherein the high-density heat sink is part of an uninterruptible power supply (UPS).

10. The system of claim 8, wherein the second printed circuit board has a first side and a second side, the first side of the second printed circuit board being in contact with the outer surface of the at least one second interconnected wall, and wherein at least one IC package is mounted on the second side of the second printed circuit board.

11. The system of claim 10, wherein the second printed circuit board is configured to have at least one vertical interconnect access (via), the at least one via allowing heat to be transferred from the at least one IC package on the second side of the second printed circuit board to the outer surface of the at least one second interconnected wall of the high-density heat sink, and wherein the at least one second interconnected wall of the high-density heat sink is configured to transfer heat from the at least one IC package to the plurality of fins.

12. The system of claim 8, further comprising a layer of thermal paste between an first side of the second printed circuit board and the outer surface of the at least one second interconnected wall of the high-density heat sink, the layer of thermal paste being configured to provide thermal coupling between the first PCB and the at least one second interconnected wall of the high-density heat sink.

13. The system of claim 8, wherein the high-density heat sink includes supports formed integrally with the first interconnected wall of the high-density heat sink, the supports being configured to elevate the body of the high-density heat sink such that at least one IC package can be secured to an outer surface of the first interconnected wall of the high-density heat sink.

14. A system for controlling dissipation of heat from a plurality of integrated circuit (IC) packages associated with an uninterruptible power supply, the system comprising:
a high-density heat sink, the high-density heat sink being fabricated from a thermally conductive material, the high-density heat sink including
a body having interconnected walls, and
a plurality of fins formed on an inner surface of at least one interconnected wall of the interconnected walls;
a fan positioned proximate to an end of the body, the fan being configured to provide directed airflow through the high-density heat sink over the plurality of fins; and
a controller coupled to the fan to control the operation of the fan, the controller being configured to operate the fan from a low speed mode to a high speed mode when one of the following conditions are met: a) an internal ambient temperature of the uninterrupted power supply is greater than a first predetermined temperature, b) a maximum load of the uninterruptible power supply is greater than a first predetermined load percent, or c) an input current of the uninterruptible power supply is greater than a first predetermined current.

15. The system of claim 14, wherein the controller is further configured to operate the fan from the high speed mode to the low speed mode when at least one of the following conditions is met d) the internal ambient temperature of the uninterrupted power supply is less than a second predetermined temperature, e) the maximum load of the uninterruptible power supply is less than a second predetermined load percent, and f) the input current of the uninterruptible power supply is less than a second predetermined current.

16. The system of claim 15, wherein the first predetermined temperature is approximately 45° C. and the second predetermined temperature is approximately 40° C.

17. The system of claim 15, wherein the first low speed mode is approximately 70% of fan speed.

18. A method of assembling a heat sink to a main printed circuit board of an uninterruptible power supply, the heat sink being configured to dissipate heat from a plurality of integrated circuit (IC) packages associated with the main printed circuit board of the uninterruptible power supply, the method comprising:
securing a high-density heat sink to the main printed circuit board of the uninterruptible power supply, the high-density heat sink being fabricated from a thermally conducting material and including
a body having interconnected walls, a first open end, and a second open end in fluid communication with the first open end, the interconnected walls defining a cavity, each interconnected wall of the interconnected walls having an outer surface and an inner surface, a first interconnected wall being of the interconnected walls secured to the main printed circuit board, and an outer surface of at least one second interconnected wall of the interconnected walls being configured to support the at least one IC package of the plurality of IC packages, and
a plurality of fins formed on an inner surface of at least one interconnected wall of the interconnected walls;
mounting at least one IC package of the plurality of IC packages on a first side of a second printed circuit board; and
securing a first side of the second printed circuit board to an outer surface of a second interconnected wall of the interconnected walls of a high-density heat sink;
in a first mode of operation, dissipating heat generated from the main printed circuit board by the first interconnected wall of the high-density heat sink; and
in a second mode of operation, dissipating heat generated from the at least one IC package by the second interconnected wall of the high-density heat sink.

19. The method of claim 18, further comprising providing directed airflow through the cavity of the high-density heat sink over the plurality of fins.

20. The method of claim 18, wherein the first PCB has at least one vertical interconnect access (via), the at least one via allowing for heat transfer between the at least one IC package and the outer surface of the interconnected wall of the high-density heat sink.

21. The method of claim 18, further comprising:
applying a thermal paste on the outer surface of the interconnected wall of the high-density heat sink, the thermal paste being configured to provide thermal coupling between the outer surface of the interconnected wall of the high-density heat sink and the lower side of the first PCB.

22. A method of controlling dissipating heat from a plurality of integrated circuit (IC) packages associated with an uninterruptible power supply, the method comprising:
mounting at least one IC package of the plurality of IC packages on a high-density heat sink, the high-density heat sink being fabricated from a thermally conducting material and including:
a body having interconnected walls, a first open end, and a second open end in fluid communication with the first open end, the interconnected walls defining a cavity, each interconnected wall of the interconnected walls having an outer surface and an inner surface, an outer surface of an interconnected wall of the interconnected walls being configured to support the at least one IC package, and
a plurality of fins formed on an inner surface of at least one wall of the interconnected walls;
moving air through the cavity of the high-density heat sink with a fan positioned proximate to the first open end or the second open end of the body, the fan being configured to provide directed airflow through the cavity of the high-density heat sink over the plurality of fins; and
controlling the operation of the fan with a controller coupled to the fan, the controller being configured to operate the fan from a first low speed mode to a second high speed mode when one of the following conditions are met a) an internal ambient temperature of the uninterrupted power supply is greater than a first predetermined temperature, b) a maximum load of the uninterruptible power supply is greater than a speed power limit of the fan, and c) an input current of the uninterruptible power supply is greater than a predetermined current.

23. The method of claim 22, wherein the controller is further configured to operate the fan from the second high speed mode to the first low speed mode when one of the following conditions is met d) an internal ambient temperature of the uninterrupted power supply is less than a second predetermined temperature, e) a maximum load of the uninterruptible power supply is less than a speed power limit of the fan, and f) an input current of the uninterruptible power supply is less than the predetermined current.

24. The method of claim 23, wherein the first predetermined temperature is approximately 45° C. and the second predetermined temperature is approximately 40° C.

25. The method of claim 23, wherein the first low speed mode is approximately 70% of fan speed.
